(19) United States
(12) Patent Application Publication
(10) Pub. No.: US 2004/0079548 A1
(43) Pub. Date: Apr. 29, 2004

(54) Electronic module

(76) Inventors: Gerhard Berghoff, Manching (DE); Helmut Heinz, Ansbach (DE); Martin Kolbinger, Buch (DE); Friedrich Nehmeier, Erlangen (DE); Johann Schneider, Wettstetten (DE); Bernhard Schuch, Neusitz (DE); Hubert Trageser, Nuernberg (DE); Ireneus Waldau, Adelschlag (DE)

Correspondence Address: FASSE PATENT ATTORNEYS, P.A., P.O. BOX 726, HAMPDEN, ME, 04444-0726, US

(21) Appl. No.: 10/468,986

(22) PCT Filed: Feb. 2, 2002
(86) PCT No.: PCT/EP02/01090

(30) Foreign Application Priority Data
Feb. 24, 2001 (DE) 101 09 083.8

(51) Int. Cl. H05K 7/20

(52) U.S. Cl. 174/252

(57) ABSTRACT

2.1 For electronic assemblies with at least one component mounted on a support body, the thermal connection thereof to a cooling body arranged on the underside of the support body is to be simplified and improved.

2.2 For this purpose, a thermally conductive, electrically insulating, permanently elastic joint layer, which produces an again-releasable joint connection, and which consists of a crosslinked polymeric base substance and at least two filler substances, is arranged between the support body and the cooling body.

2.3 Electronic assembly with joint layer between circuit boards and cooling plates.

Electronic assemblies, in the operation of which a high dissipated power arises, are utilized in many fields of application; especially this is the case for electronic assemblies with power components, such as, for example, power modules for actuating electronic components or further assemblies. The components of the electronic assembly are mounted on a suitable support body (for example on the upper side of a circuit board); especially in connection with power modules, surface mountable power components are often utilized, which rest with their backside connection surface on the support body. For transferring away the heat of the dissipated power of the components (especially of the dissipated power of power components), the support body is applied or arranged on a metallic cooling body (for example an aluminum plate), through which the dissipated power can be conveyed further to a cooling system if applicable.

In this context it is known from the DE 198 42 590 A1 and the DE 199 09 505 A1, to separate the support body from the cooling body with respect to potential by an insulation film applied on the underside of the support body. Disadvantageous in the use of such an insulation film is its low thermal conductivity, the high sticking or adhesive bonding force (the components support body and cooling body bonded with one another can no longer be disassembled without destruction thereof and without leaving residues), the low adhesive characteristics (for the durable connection or joining of support body and cooling body additional connecting or bonding elements are thus necessary), the often too-small insulation spacing distance for the electrical insulation due to the small thickness of the insulation film, and the incomplete filling-out of non-uniformities or unevenness (thus, hollow spaces remain in the joint surfaces).

The underlying object of the invention is to propose an electronic assembly with a simple construction, a broad field of application, and advantageous characteristics with respect to the thermal transfer, the reliability, the costs and the fabrication process.

This object is achieved according to the invention through the characteristic feature in the characterizing portion of the Patent claim 1. Advantageous embodiments of the invention are the subject of the further patent claims.

According to the invention, an electrically isolating or insulating, thermally conductive, and permanently elastic joint layer, that is to say a joint layer with a high electrical isolation or insulation, a low thermal resistance and a high flexibility in a wide temperature range, is arranged between and the support body provided with a conductor path or track structure (conductor paths and contact surfaces) for receiving the components of the electronic assembly and the cooling body; the joint layer consists as a “filled” polymer of a material mixture of a crosslinked polymeric base substance and plural filler, loading or additive substances, and is produced by means of two different (liquid) reaction partners of uncrosslinked polymers; this joint layer effectuates an adhesive, hollow-space-free and again releasable joint connection between the two joint parts (joint partners) support body and cooling body, which are thereby held together in every position and can again be separated in a simple manner without destruction and free of residues. The two separately stored (liquid) reaction partners contain no dangerous substances and can be stored without danger under ambient environmental conditions (at ambient environmental temperatures) without safety precautions. Both reaction partners contain as components respectively one base substance embodied as an uncrosslinked polymer (for example a silicone, a silane or a polyurethane), to which are admixed respectively two additive or filler or loading substances for ensuring the desired characteristics of the joint layer (especially the thermal and electrical characteristics of the joint layer) and respectively a third additive or filler or loading substance for carrying out a (crosslinking) reaction in the two reaction partners:

as the first additive or filler substance, for ensuring the requirements with respect to electrical insulation and good thermal connection of the joint layer, electrically insulating particles (solid materials) with high thermal conductivity are provided, for example the first additive or filler substance is a ceramic powder, for example, of boron nitride or of a mixture of Al₂O₃ and AlN; preferably, the same first additive or filler substance (and therewith a first filler substance with the same thermal conductivity) is contained in the same quantity proportion or ratio in both reaction partners—for example the base substance of both reaction partners contains, as the first filler substance, electrically insulating and thermally conductive particles with a proportion of respectively 1% to 50% and a diameter of ≦30 μm.

as the second additive or filler substance, for ensuring a defined electrical insulation spacing distance and therewith for avoiding a direct contact (of the underside) of the support body with the cooling body, there are provided incompressible particles (solid materials) functioning as spacers that ensure a minimum thickness of the joint layer, for example ball shaped particles (for example hollow spheres or solid spheres), for example of glass, synthetic, or ceramic; preferably the same second filler substance is contained in the same quantity proportion or ratio in both reaction partners—for example the base substance of both reaction partners contains, as the second filler substance, incompressible particles with a proportion of respectively 0.5% to 5% and a larger diameter than the first filler substance, for example of approximately 150 μm.

as the third additive or filler substance, for carrying out the crosslinking reaction, in the two reaction partners respectively one reaction substance is provided; for this purpose, a reaction substance functioning as a crosslinking substance (this effectuates a three-dimensional crosslinking reaction of the uncrosslinked polymer of the base substance), for example a hydrogen-containing crosslinking agent, is contained in one of the two reaction partners, and a reaction substance functioning as a catalyst for activating and for accelerating the crosslinking reaction, for example a platinum catalyst, is contained in the other one of the two reaction partners. For example, the base substance of the one of the two reaction partners contains a hydrogen-containing crosslinking agent as the crosslinking substance with a proportion of 0.1% to 5%, and the base substance of the other one of the two reaction partners contains particles of a platinum catalyst as a trace proportion.

Before the joining of the two joint partners support body and cooling body, the two separately stored reaction partners existing in a liquid condition are brought together (for example stirred together or mixed in a static mixing pipe or tube), whereby a reaction is triggered in both reaction partners; in particular, upon contact of the two reaction substances, that is to say of the catalyst in one reaction partner with the crosslinking substance in the other reaction partner, a three-dimensional (spatial) crosslinking reaction of the uncrosslinked polymer of the base substance is carried out (for example a polyaddition as an addition crosslinking); thereby the two reaction partners react with one another, without giving rise to fission products in the crosslinking reaction (for example the polyaddition), especially, no bubble formation occurs during the crosslinking reaction, and no solvent agents arise. Due to the accelerating effect of the catalyst, the crosslinking reaction already proceeds at ambient environmental temperature, whereby at higher temperatures the reaction speed can be increased or the reaction time can be shortened. Necessitated by the crosslinking of the polymers, the original liquid mixture of the two liquid reaction partners is transitioned into a gel-like pasty condition, and this material mixture containing the components of the two reaction partners (base substance, first filler substance, second filler substance, and the respective third filler substance) is further processed as joint paste; for example the pasty (gel-like) condition of the material mixture of the two reaction partners can be maintained 15 minutes to several hours, so that during this time span as a so-called “potting time” a good workability of the joint paste is possible (this “potting time” is the time span from the time point at the beginning of the mixing until the time point at which the viscosity of the material mixture reaches a limit viscosity that still allows a working of the material mixture).

In the joining of the two joint partners (joint parts) support body and cooling body, the joint paste is applied onto one of the two joint surfaces (that is to say on the surface of one of the two joint partners) (preferably onto the cooling body), and the other joint surface (that is to say the surface of the other one of the two joint partners) is brought into contact therewith after the positioning of the two joint partners; in this context the joint paste can be applied onto any desired (surface) materials of the cooling body and the support body, for example onto metallic, ceramic or polymeric surfaces, especially it can also be utilized for the joining of a ceramic circuit board with a metallic base plate. In connection with the mechanical connecting of the two joint partners positioned with respect to each other (that is to say under pressure), the joint paste flows and spreads out (even at ambient environmental conditions, that is to say at ambient environmental temperature), so that on the one hand the surfaces (joint surfaces) of the two joint partners that are positioned with respect to one another are completely wetted (all hollow spaces and unevennesses are filled out, so that the joint surfaces are free of hollow spaces and roughnesses are evened out), and on the other hand metal surfaces (especially conductor paths and contact surfaces of a conductor path structure or electrical through-contacts in the support body) located on the surface of the support body are electrically insulated and protected against corrosion. Due to the viscosity of the joint paste containing the base substance (crosslinked polymer), the first filler substance (electrically insulating, thermally conductive particles), the second filler substance (incompressible particles as spacers) and the respective third filler substance (crosslinking substance on the one hand, catalyst on the other hand), the two joint partners (joint parts) support body and cooling body, which have been brought together, stick or adhere durably or permanently in every position onto one another (the two joint partners are thereby durably held together in every position) even at ambient environmental conditions (at ambient environmental temperature), because especially the crosslinked polymer as the base substance of the two reaction partners, and therewith the joint paste, adapts itself onto the joint surfaces and therewith adhesively bonds together the two joint partners without adhesion promoters or adhesives. For ensuring a durable and stable connection of the two joint partners (composite joined parts) that have been joined with one another, even at increased mechanical load of the electronic assembly, the two joint partners support body and cooling body can additionally be connected with one another by securing means, for example can be screwed together with one another; through the securing means (for example embodied as screws) an electrical connection between the support body and the cooling body can be simultaneously realized.

After the joining of the two joint partners, the joint paste is cured (this is possible at ambient environmental conditions) for forming the joint layer, whereby one obtains an electrically insulating, thermally conductive, minimum thickness ensuring, durably or permanently elastic connection of the two joint partners (composite joined parts) that have been joined or bonded with one another, in a large temperature range, for example in a temperature range from −40° C. to +150° C.; in this context, at ambient environmental conditions (at ambient environmental temperature) the curing time amounts to, for example, 1 hour to 10 hours, whereby at higher temperatures the curing time can be reduced (for example the curing time then can be in the range of minutes).

The heat transport of the dissipated power of the components that are soldered (for example by means of a reflow soldering process) onto the upper side of the support body, from the upper side of the support body to the underside of the support body, which is preferably supported by thermal through-contacts or vias in the support body, the dissipated power on the underside of the support body is spread out through the connection or joint layer onto the entire surface of the cooling body, and from the latter is then transferred away externally to the surrounding environment through suitable measures (for example by means of a cooling circuit or through the securing means provided for connecting the cooling body and the support body).

If necessary, the two joint partners (composite joined parts) that have been connected or bonded with one another can again be released or separated from one another in a simple manner even after the curing of the joint paste for forming the connecting or joint layer, especially through mechanical forces acting perpendicularly or vertically onto the surface of one of the two composite joined parts support body and cooling body, for example by perpendicular tension on the upper side of the two joint partners (composite joined parts) that have been joined or bonded with one another, or by perpendicular pressure onto an accessible partial area on the underside of the two joint partners (composite joined parts) that have been connected or bonded with one another. The joint or connection layer between the two joint partners (composite joined parts) that have been connected or bonded with one another is thereby separated without destruction and without further effort (especially no shearing of the two composite joined parts is necessary), so that the separated joint partners can be reused, especially because also the material of the joint layer can be removed from the joint surfaces (surfaces) of the separated joint partners without assisting or auxiliary substances (residue-free release or separation of the joint layer through peeling-off, rubbing-off, scrubbing-off, dry wiping-off, etc). The removed material of the joint layer does not represent any dangerous material and can therefore be disposed of without problems.

In the proposed safe and simple method for the production of an electronic assembly, a simple, durably or permanently elastic joint connection of the two joint partners support body and cooling body can be realized, advantageously with low costs, and without detracting from the thermal transfer, wherein the joint connection can just as simply be once again released or separated without residues, and without destruction, damage or impairment of the two joint partners that had been connected with one another. This durably or permanently elastic joint connection is further characterized, due to the selected material mixture of the joint layer, through good characteristics or properties, especially through complete covering of the joint surfaces of the two joint partners, through a good thermal conductivity for transferring away or further conveying the dissipated power of the components of the electronic assembly to the cooling body, through a good electrical insulation with sufficient insulation spacing, and through good adhesive characteristics for fixing and bonding together the two joint partners.

The method shall be described in the following with regard to an example embodiment in connection with the drawing. In this context it is shown in:

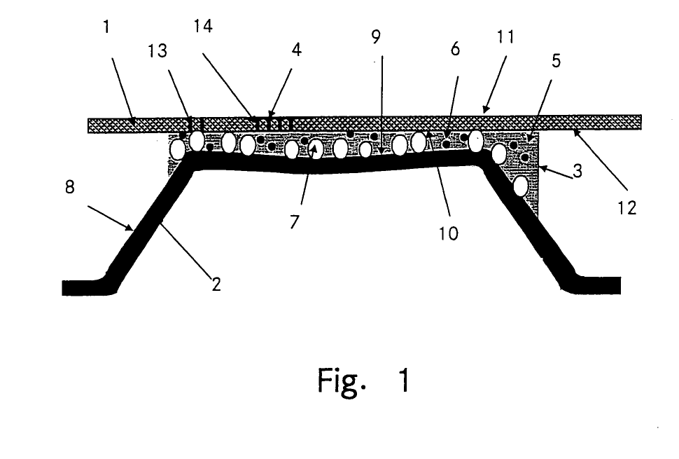

FIG. 1 a sectional illustration of the electronic assembly with a cut-out portion of the joint partners support body and cooling body that are connected by the joint layer.

The circuit arrangement of the electronic assembly, for example embodied as a power module of a motor vehicle, that is arranged on the upper side 11 of a support body 1 for example embodied as a circuit board, comprises also at least one power component in addition to further active and passive electronic components; the components of the circuit arrangement are soldered, for example by means of a reflow soldering process, onto the upper side 11 (component mounting side) of the circuit board 1, and are contacted with contact surfaces (pads) and/or conductor paths or tracks of the metallic conductor path structure 4 applied on the circuit board 1. Furthermore, electrical through-contacts 13 (electrical vias) and thermal through-contacts 14 (thermal vias) are provided from the upper side 11 of the circuit board 1 to the underside 12 of the circuit board 1; the thermal through-contacts serve for vertically transferring away the dissipated power arising during the operation of the electronic assembly—especially through the power components of the circuit arrangement—from the upper side 11 of the circuit board 1 to the underside 12 of the circuit board 1. From the underside 12 of the circuit board 1, the dissipated power is conveyed away to a cooling system by means of the metallic cooling body 2, which is, for example, embodied as a cooling metal plate or sheet, for example consisting of aluminum. A thermally conductive, electrically insulating joint layer 3 is provided for the electrical insulation between the underside 12 of the circuit board 1 and the cooling metal sheet or plate as the cooling body 2.

After the mounting and contacting of the components of the circuit arrangement on the upper side 11 of the circuit board 1, this joint layer 3 is formed through curing of a joint paste that is entirely surfacially applied onto the cooling body 2 and that arises by means of the reaction of two separately stored liquid reaction partners. The first reaction partner contains as components an uncrosslinked polymeric base substance 5 for example consisting of an uncrosslinked silicone, a ceramic powder as a first filler substance 6 for example consisting of a mixture of Al₂O₃ and AlN with a proportion in the range from for example 20% to 60% and a particle size in the range from for example 1 μm to 100 μm, solid balls or spheres for example consisting of glass as a second filler substance 7 with a proportion in the range from 1% to 3% and a diameter in the range from for example 100 μm to 200 μm, as well as a crosslinking substance consisting of polysiloxane compounds as a third filler substance. The second reaction partner essentially contains the same components as the first reaction partner, that is to say a polymeric base substance 5 for example consisting of an uncrosslinked silicone, a ceramic powder as a first filler substance 6 for example consisting of a mixture of Al₂O₃ and AlN with a proportion in the range from for example 20% to 60% and a particle size in the range from for example 1 μm to 100 μm, solid balls or spheres for example consisting of glass as a second filler substance 7 with a proportion in the range from 1% to 3% and a diameter in the range from for example 100 μm to 200 μm; deviating from the first reaction partner, the second reaction partner contains a catalyst consisting of platinum as a third filler substance. In the mixing of the two reaction partners, due to the respective third filler substance respectively functioning as a reaction substance (crosslinking substance on the one hand and catalyst on the other hand), a polyaddition and therewith a crosslinking of the uncrosslinked polymeric base substance 5 is carried out, whereby a gel-like pasty reaction product arises as a joint paste; for example this joint paste is formed by mixing of the two liquid reaction partners at a temperature of 25° C. The joint paste is entirely surfacially applied with a layer thickness of, for example, 250 μm onto the upper side 8 of the cooling body 2 serving as a first joint surface 9 (the layer thickness of the joint paste is thereby slightly greater than the minimum layer thickness prescribed by the diameter of the incompressible glass balls or spheres of the second filler substance 7 as spacers), and the underside 12 of the circuit board 1 serving as the second joint surface 10 correspondingly positioned relative to the first joint surface 9. The respective joint surfaces 9, 10 of the two joint partners cooling body 2 and circuit board 1 are pressed against one another and fixed relative to one another by the adhesive hollow-space-free connection or bonding of the joint paste; subsequently the joint paste is cured for forming the joint layer 3, for example two hours at a temperature of 25° C. After the curing, one obtains through the joint layer 3 a durably or permanently elastic connection or joining of the two composite joined parts cooling body 2 and circuit board 1; especially for the application of the power module in a motor vehicle, and the herewith associated mechanical loading, can the two composite joined parts cooling body 2 and circuit board 1 can be additionally connected with one another by securing screws, through which simultaneously an electrical connection between the circuit board 1 and the cooling body 2 is realized. In the event of defects or a provided exchange of individual component parts (composite joined parts) of the electronic assembly, the two composite joined parts cooling body 2 and circuit board 1 can again be separated through (perpendicular or vertical) tension from the upper side of the circuit board 1 or through (perpendicular or vertical) pressure onto the upper side 8 of the cooling body 2, in a destruction-free manner (without shear forces), and the separated joint partners cooling body 2 and circuit board 1, after the removal of the joint layer 3 from the surface of the joint surfaces 9, 10 (for example achieved by wiping-off) can be further used if applicable.

The electronic assembly, for example utilized as a power module in a motor vehicle, is, for example, embodied as a control device for electric motors and a heating system of a motor vehicle. For this purpose, the circuit arrangement of the control device comprises sixteen components as power switches; the dissipated power of the power switches of, for example, 25 W is transferred away from the upper side 11 of the circuit board 1 through the joint layer 3 and the cooling body 2 to a cooling system.

1. Electronic assembly with at least one component mounted on a support body (1), and with a cooling body (2) arranged on the underside (12) of the support body (1) for transferring away the dissipated power of the at least one component, characterized in that a thermally conductive, electrically insulating, permanently elastic joint layer (3) creating a joint connection, of a material mixture containing a crosslinked polymeric base substance (5) and at least two filler substances (6), (7), is arranged between the support body (1) and the cooling body (2).

2. Electronic assembly according to claim 1, characterized in that the joint layer (3) contains thermally conductive, electrically insulating particles as a first filler substance (6) and incompressible particles as a second filler substance (7).

3. Electronic assembly according to claim 2, characterized in that the incompressible particles of the second filler substance (7) are larger than the particles of the first filler substance (6).

4. Electronic assembly according to one of the claims 1 to 3, characterized in that the material mixture of the joint layer (3) is formed by the reaction of two reaction partners respectively containing the uncrosslinked polymeric base substance (5), the first filler substance (6), the second filler substance (7) and a third filler substance as a reaction substance.

5. Electronic assembly according to claim 4, characterized in that, as the third filler substance, a crosslinking substance effectuating the crosslinking of the uncrosslinked polymeric base substance (5) is contained in the first reaction partner, and a catalyst activating the reaction of the two reaction partners is contained in the second reaction partner.

6. Electronic assembly according to claim 4 or 5, characterized in that the joint paste arising from the reaction of the two reaction partners is applied in the pasty condition onto the support body (1) and/or the cooling body (2) and is cured for forming the joint layer (3).

7. Electronic assembly according to one of the claims 1 to 6, characterized in that the joint connection between the support body (1) and the cooling body (2) realized through the joint layer (3) is again releasable by pressure onto the support body (1) or onto the cooling body (2) or by tension on the support body (1) or on the cooling body (2).

8. Electronic assembly according to one of the claims 1 to 7, characterized in that the support body (1) is connected with the cooling body (2) by means of additional securing means.

9. Electronic assembly according to claim 8, characterized in that an electrically conducting connection between the support body (1) and the cooling body (2) is realized by the securing means.
